(19) United States
(12) Patent Application Publication
(10) Pub. No.: US 2004/0252463 A1
(43) Pub. Date: Dec. 16, 2004

(54) Mounting device for heat sink

(76) Inventor: Wow Wu, Shenzhen (CN)

Correspondence Address: WEI TE CHUNG, FOXCONN INTERNATIONAL, INC., 1650 MEMOREX DRIVE, SANTA CLARA, CA, 95050, US

(21) Appl. No.: 10/815,372

(22) Filed: Mar. 31, 2004

(30) Foreign Application Priority Data
Jun. 11, 2003 (TW) 92210678

(51) Int. Cl. H05K 7/20

(52) U.S. Cl. 361/719

(57) ABSTRACT

A mounting device (20), for mounting a heat sink (10) to a circuit board (50) on which an electronic component (60) is mounted, includes a body (22). The body includes an opening (24) for extension of the electronic component to contact the base and a plurality of longitudinal and lateral beams (25, 27) surrounding the electronic component and being sandwiched between the base and the circuit board. A plurality of fasteners (26) is formed on a top face of the longitudinal beams and engaged in cutouts (16) defined in the base, respectively. A pair of latches (32) is formed on a bottom face of the longitudinal beams and engaged in a pair of locking sots (54) defined in the base, respectively. Four pairs of feet are formed on four corner portions of a bottom face of the body and are received in locating openings of the circuit board, respectively.

### BACKGROUND OF THE INVENTION

1. Field of the Invention

The present invention relates to a device for mounting a heat sink to a circuit board, and particularly to a mounting device that can readily and conveniently mount a heat sink to a circuit board.

2. Related Art

As computer technology continues to advance, electronic components such as central processing units (CPUs) of computers are being made to provide faster operational speeds and greater functional capabilities. When a CPU operates at high speed in a computer enclosure, its temperature can increase greatly. It is desirable to dissipate the generated heat quickly, for example by using a heat sink attached to the CPU in the enclosure. This allows the CPU and other electronic components in the enclosure to function within their normal temperature operating temperature ranges, thereby assuring the quality of data management, storage and transfer. Oftentimes, a clip is required for mounting the heat sink to the CPU.

In earlier times, a linear type of wire clip was widely used. The linear clip is received in a groove defined between two adjacent medial fins of the heat sink, and is engaged with a circuit board on which the CPU is mounted. However, in many modem applications such as when a large heat sink is used, the linear clip cannot firmly retain the heat sink against the CPU. Subsequently, wider plate types of clips were developed. The plate clip is received in a specially widened groove defined between two adjacent medial fins of a heat sink, and engaged with the circuit board. However, the widened groove takes up space that would otherwise be utilized to provide more fins for the heat sink. In effect, the plate clip reduces a heat dissipating area of the heat sink, and reduces the heat dissipating capability of the heat sink. Further, a combined clip and retention module assembly was developed. A pair of clips presses on opposite sides of the heat sink, and engages with a retention module which is mounted on a circuit board. However, use of the retention module increases the number of parts of the assembly, and inflates costs.

### SUMMARY OF THE INVENTION

Accordingly, an object of the present invention is to provide a mounting device for a heat sink which allows a heat dissipating area of the heat sink to be maximized.

Another object of the present invention is to provide a mounting device which firmly mounts a heat sink to a circuit board without the need for additional auxiliary components.

To achieve the above-mentioned objects, a mounting device in accordance with the present invention comprises a body. The body comprises an opening for extension of an electronic component of a circuit board to contact a base of a heat sink, and a plurality of longitudinal and lateral beams surrounding the electronic component and being sandwiched between the base and the circuit board. A plurality of fasteners is formed on a top face of the longitudinal beams and engaged in cutouts defined in the base respectively. A pair of latches is formed on a bottom face of the longitudinal beams and engaged in a pair of locking sots defined in the base respectively. Four pairs of feet are formed on four corner portions of a bottom face of the body and are received in locating openings of the circuit board, respectively.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded, isometric view of a mounting device in accordance with the present invention, a heat sink, an electronic component, and a circuit board;

FIG. 2 is similar to FIG. 1, but showing the components thereof inverted; and

FIG. 3 is an assembled view of FIG. 2.

### DATAILED DESCRIPTION OF THE INVENTION

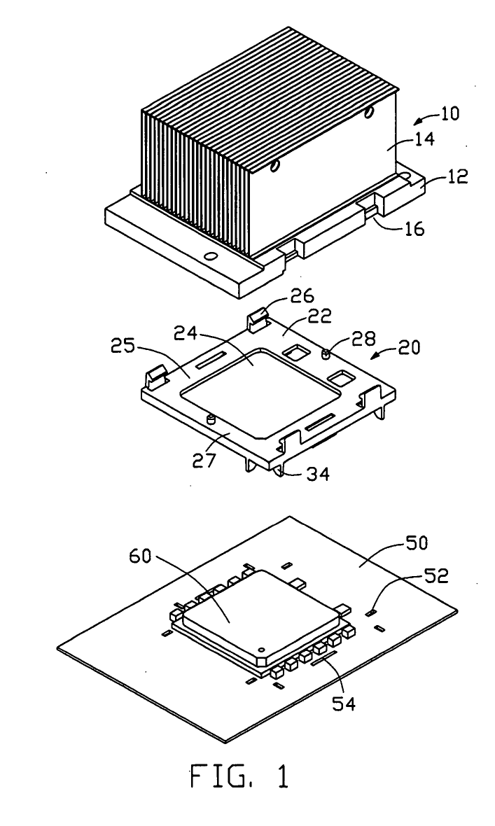

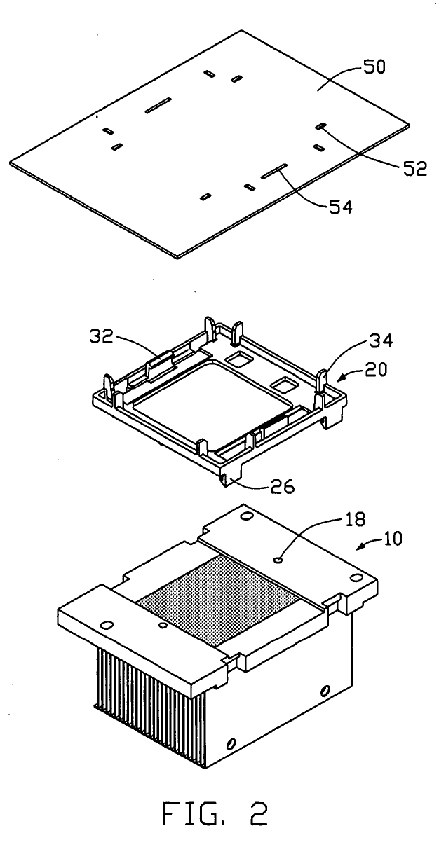

FIGS. 1-2 show a mounting device 20 in accordance with a preferred embodiment of the present invention, for mounting a heat sink 10 to a circuit board 50. The heat sink 10 comprises a base 12, and a plurality of parallel fins 14 extending upwardly from the base 12. A pair of cutouts 16 is defined in each of opposite longitudinal side edges of the base 12. A pair of holes 18 is defined in a bottom face of the base 12, at opposite lateral side portions of the base 12 respectively. The circuit board 50 has an electronic component 60 mounted thereon. The electronic component 60 may, for example, be a CPU. Four pairs of locating openings 52 are defined in the circuit board 50, adjacent four corners of the electronic component 60 respectively. The locating openings 52 in each pair of locating openings 52 are oriented perpendicular to each other. A pair of locking slots 54 is defined in the circuit board 50 on opposite longitudinal sides of the electronic component 60 respectively.

The mounting device 20 comprises a main body 22. An opening 24 is defined in a middle of the body 22. A pair of longitudinal beams 25 and a pair of lateral beams 27 are thus formed around the opening 24. A pair of fasteners 26 is formed on respective opposite ends of a top face of each longitudinal beam 25, for engaging in corresponding cutouts 16 of the heat sink 10. A post 28 is formed on a middle of a top face of each lateral beam 27, for being received in a corresponding hole 18 of the heat sink 10. A latch 32 is formed on a bottom face of each of the longitudinal beams 25, for engaging in a corresponding locking slot 54 of the circuit board 50. Four pairs of feet 34 are formed on four corner portions of a bottom face of the body 22, for engaging in the locating openings 52 of the circuit board 50.

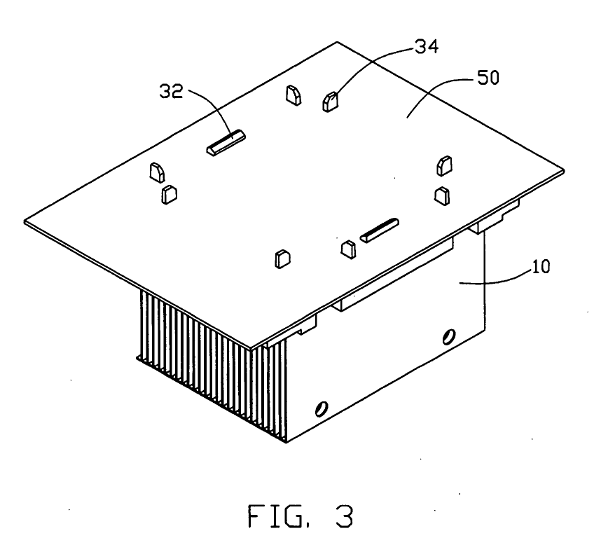

Referring also to FIG. 3, in assembly, the mounting device 20 is mounted onto the bottom face of the base 12 of the heat sink 10. The posts 28 are fittingly received in the holes 18 of the heat sink 10. The fasteners 26 of the mounting device 20 are snappingly engaged in the cutouts 16 of the heat sink 10. The combined heat sink 10 and mounting device 20 is then mounted onto the circuit board 50, with the opening 24 of the mounting device 20 receiving the electronic component 60 therein. The feet 34 are extended through the corresponding locating openings 52 of the circuit board 50, thereby locating the combined heat sink 10 and mounting device 20 on the circuit board 50. The latches 32 are snappingly engaged in the locking slots 54 of the circuit board 50. Thus, the heat sink 10 is firmly and securely mounted onto the circuit board 50 by means of the mounting device 20.

In the present invention, the mounting device 20 is sandwiched between the heat sink 10 and the circuit board 50, and does not extend through any of the fins 14 of the heat sink 10. Because the fins 14 are unaltered, they provide a maximum possible heat dissipating area for the heat sink 10. Moreover, no additional auxiliary element is needed for the mounting device 20 to mount the heat sink 10 to the circuit board 50.

It is understood that the invention may be embodied in other forms without departing from the spirit thereof. Thus, the present example and embodiment is to be considered in all respects as illustrative and not restrictive, and the invention is not to be limited to the details given herein.

What is claimed is:

1. A mounting device assembly comprising:
a circuit board having an electronic component mounted thereon;
a heat sink comprising a base, and a plurality of fins arranged on the base;
a unitary mounting device for mounting the heat sink to the circuit board, the mounting device comprising a body defining an opening for receiving the electronic component therethrough such that the electronic component contacts the base, the body comprising a plurality of beams surrounding the electronic component and being sandwiched between the base and the circuit board;
locking means for locking the heat sink to the mounting device without interference to the fins; and
latching means for latching the mounting device to the circuit board.

2. The mounting device assembly as claimed in claim 1, wherein the beams comprises a pair of longitudinal beams, and the locking means comprises a plurality of cutouts defined in opposite longitudinal sides of the base of the heat sink, and a plurality of fasteners formed on the longitudinal beams of the mounting device and engaging in the cutouts.

3. The mounting device assembly as claimed in claim 2, wherein the latching means comprises a pair of locking slots defined in the circuit board on opposite sides of the electronic component, and a pair of latches formed on bottoms of the longitudinal beams and engaging in the locking slots respectively.

4. The mounting device assembly as claimed in claim 3, wherein the circuit board defines a plurality of pairs of locating openings surrounding the electronic component, and the body of the mounting device comprises a plurality of pairs of feet received in the locating openings respectively.

5. The mounting device assembly as claimed in claim 3, wherein the base of the heat sink defines a pair of holes in opposite lateral side portions thereof, the beams further comprise a pair of lateral beams, a pair of posts is formed on the lateral beams, and the posts are fittingly received in the holes.

6. A mounting device assembly comprising:
a circuit board having an electronic component mounted thereon;
a heat sink comprising a base, and a plurality of fins provided on the base; and
a mounting device for mounting the heat sink to the circuit board, the mounting device comprising:
a body defining an opening for extension of the electronic component therethrough to contact the base, and comprising a plurality of beams surrounding the electronic component and being sandwiched between the base and the circuit board;
engaging means integrally formed from the body for engaging with the heat sink at outsides of the fins; and
latching means integrally formed from the body for latching the mounting device to the circuit board.

7. The mounting device assembly as claimed in claim 6, wherein the base of the heat sink defines a plurality of cutouts in opposite longitudinal sides thereof, the beams comprise a pair of longitudinal beams, and the engaging means comprises a plurality of fasteners formed on the longitudinal beams and engaging in the cutouts.

8. The mounting device assembly as claimed in claim 7, wherein the circuit board defines a pair of locking slots on opposite sides of the electronic component, and the latching means comprises a pair of latches formed on bottoms of the longitudinal beams and engaging in the locking slots.

9. The mounting device assembly as claimed in claim 8, wherein the circuit board defines a plurality of pairs of locating openings surrounding the electronic component, and the body of the mounting device comprises a plurality of pairs of feet received in the locating openings respectively.

10. The mounting device assembly as claimed in claim 8, wherein the base of the heat sink defines a pair of holes in opposite lateral side portions thereof, the beams further comprise a pair of lateral beams, a pair of posts is formed on the lateral beams, and the posts are fittingly received in the holes.

11. A mounting device assembly comprising:
a circuit board having an electronic component mounted on a surface thereof;
a heat sink;
a mounting device being arranged between the circuit board and the heat sink and around the electronic component;
fasteners being formed on one of the mounting device and the heat sink and snappingly engaged with the other of the mounting device and the heat sink, thus fastening the mounting device to the heat sink; and
latches being formed on one of the mounting device and the circuit board and snappingly engaged with the other of the mounting device and the circuit board, thus latching the mounting device to the circuit board.

12. The mounting device assembly of claim 11, wherein the mounting device is a substantial rectangular plate.

13. The mounting device assembly of claim 12, wherein four pairs of feet are formed on four corner portions of the mounting device, each pair of the feet are oriented perpendicular to each other and fittingly engaged in the circuit board.

14. The mounting device assembly of claim 11, wherein the fasteners are formed on the mounting device and snap a base plate of the heat sink which is in contact with the electronic component.

15. The mounting device assembly of claim 11, wherein the latches are formed on the mounting device and snap a surface of the circuit board opposite to the surface where the electronic component mounted.

16. The mounting device assembly of claim 11, wherein said mounting device is provided with an upward plane supporting a base of the heat sink, and defines an opening to allow one of said heat sink and said electronic component to extend therethrough to contact the other.
